(19) United States
(12) Patent Application Publication
(10) Pub. No.: US 2026/0143781 A1
(43) Pub. Date: May 21, 2026

(54) Laminate Stacking Structures

(71) Applicant: Taiwan Semiconductor Manufacturing Company, Ltd., Hsin-Chu (TW)

(72) Inventors: Szu-Hua CHEN, Tainan City (TW); Ju-Yu HOO, Hsinchu (TW); Wei-Yen WOON, Taoyuan City (TW); Szuya LIAO, Hsinchu (TW)

(21) Appl. No.: 19/198,718

(22) Filed: May 5, 2025

Related U.S. Application Data
(60) Provisional application No. 63/722,158, filed on Nov. 19, 2024.

(51) Int. Cl. H10D 64/66; H10D 30/00; H10D 64/01

(52) U.S. Cl. CPC H10D 64/675; H10D 30/509; H10D 64/021

(57) ABSTRACT

Electrically insulating materials and/or structures are disclosed herein for implementation in semiconductor devices, such as transistors. An exemplary electrically insulating layer is a dielectric layer having a boron-and-nitrogen containing laminate structure. The boron-and-nitrogen containing laminate structure includes at least one crystalline boron nitride layer (e.g., a hexagonal boron nitride layer) and at least one amorphous boron nitride layer. In some embodiments, the dielectric layer is implemented in a transistor. For example, the transistor includes a gate spacer and/or an inner spacer, and the dielectric layer is the gate spacer, the inner spacer, or both. In another example, the dielectric layer is a contact etch stop layer, which may be formed over the transistor. In another example, the dielectric layer is, or forms a portion of, a gate isolation layer between a gate of the transistor and a gate of another transistor.

This is a non-provisional application of and claims benefit of U.S. Provisional Patent Application Ser. No. 63/722,158, filed Nov. 19, 2024, the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (e.g., minimum IC feature sizes), thereby improving production efficiency and lowering associated costs. For examples, reducing sizes of transistors (and thus reducing dimensions thereof) in ICs may reduce power supply voltages and/or threshold voltages needed for operating the transistors. However, such improvements may be negated by increases in leakage current that may arise with reduced dimensions of insulating materials in scaled ICs. Improvements are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 depicts a laminated dielectric film, in portion or entirety, which may form a portion of a semiconductor device, according to various aspects of the present disclosure.

FIG. 2 is a schematic diagram of a laminated dielectric film, in portion or entirety, such as that of FIG. 1, according to various aspects of the present disclosure.

FIG. 3 provides experimental current-voltage (I-V) characteristics for different laminated dielectric structures according to various aspects of the present disclosure.

FIG. 4 depicts a precursor that may be used to form a laminated dielectric film, such as that of FIG. 1, according to various aspects of the present disclosure.

FIG. 5 is a flow chart of a method, in portion or entirety, of forming a laminated dielectric film, such as that of FIG. 1, according to various aspects of the present disclosure.

FIG. 6 is a cross-sectional view of a transistor, in portion or entirety, that may incorporate a laminated dielectric film, such as that of FIG. 1 and/or other laminated dielectric films described herein, according to various aspects of the present disclosure.

FIGS. 7A-7D are enlarged views, in portion or entirety, of different configurations of a portion of a transistor that may incorporate a laminated dielectric film, such as a portion of the transistor of FIG. 6, according to various aspects of the present disclosure.

FIGS. 8A-8D are enlarged views, in portion or entirety, of different configurations of another portion of the transistor that may incorporate a laminated dielectric film, such as another portion of the transistor of FIG. 6, according to various aspects of the present disclosure.

FIGS. 9A-9D are enlarged views, in portion or entirety, of different configurations of a portion of an interconnect structure, such as connected to the transistor of FIG. 6, that may incorporate a laminated dielectric film, according to various aspects of the present disclosure.

FIG. 10 is a cross-sectional view of another transistor, in portion or entirety, that may incorporate a laminated dielectric film, such as that of FIG. 1 and/or other laminated dielectric films described herein, according to various aspects of the present disclosure.

FIGS. 11A-11D are enlarged views, in portion or entirety, of different configurations of yet another portion of a transistor that may incorporate a laminated dielectric film, such a portion of the transistor of FIG. 10, according to various aspects of the present disclosure.

FIG. 12 is a cross-sectional view of a device, in portion or entirety, that may incorporate a laminated dielectric film, such as that of FIG. 1 and/or other laminated dielectric films described herein, according to various aspects of the present disclosure.

FIGS. 13A-13D are enlarged views, in portion or entirety, of different configurations of a portion of a device that may incorporate a laminated dielectric film, such as a portion of the device of FIG. 12, according to various aspects of the present disclosure.

FIG. 14 is a cross-sectional view of a device, in portion or entirety, that may incorporate a laminated dielectric film, such as that of FIG. 1 and/or other laminated dielectric films described herein, according to various aspects of the present disclosure.

FIGS. 15A-15D are enlarged views, in portion or entirety, of different configurations of a portion of a device that may incorporate a laminated dielectric film, such as a portion of the device of FIG. 14, according to various aspects of the present disclosure.

FIG. 16 is a cross-sectional view of a device, in portion or entirety, that may incorporate a laminated dielectric film, such as that of FIG. 1 and/or other laminated dielectric films described herein, according to various aspects of the present disclosure.

FIGS. 17A-17D are enlarged views, in portion or entirety, of different configurations of a portion of a device that may incorporate a laminated dielectric film, such as a portion of the device of FIG. 16, according to various aspects of the present disclosure.

### DETAILED DESCRIPTION

The present disclosure is generally directed to electrically insulating materials (e.g., dielectric materials) and/or structures for reducing leakage current.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Leakage current has arisen as a significant challenge as integrated circuit (IC) technology nodes scale (i.e., by increasing device density (i.e., the number of interconnected devices in a given chip area) and/or decreasing geometry size (e.g., dimensions and/or sizes of device features and/or spacings therebetween)). For example, significant increases in leakage current have been observed as thicknesses of insulating materials have decreased in scaled IC technology nodes. The present disclosure thus proposes electrically insulating materials (e.g., dielectric materials) and/or structures for reducing leakage current. In some embodiments, an electrically insulating layer has a laminate structure that includes at least one crystalline boron nitride layer and at least one amorphous boron nitride layer (i.e., the electrically insulating layer has a boron-and-nitrogen containing laminate structure). For example, the electrically insulating layer may have a laminate structure that includes an amorphous boron nitride (aBN) layer and a crystalline boron nitride layer. In some embodiments, a thickness of the crystalline boron nitride layer is greater than a thickness of the amorphous boron nitride layer. In another example, the electrically insulating layer may have a laminate structure that includes an amorphous boron nitride layer disposed between a first crystalline boron nitride layer and a second crystalline boron nitride layer. In some embodiments, the crystalline boron nitride layer(s) is a hexagonal boron nitride (hBN) layer(s). The electrically insulating materials and/or structures disclosed herein may be implemented as gate spacers, inner spacers, etch stop layers, gate isolation layers, other layers and/or features of semiconductor devices, or combinations thereof.

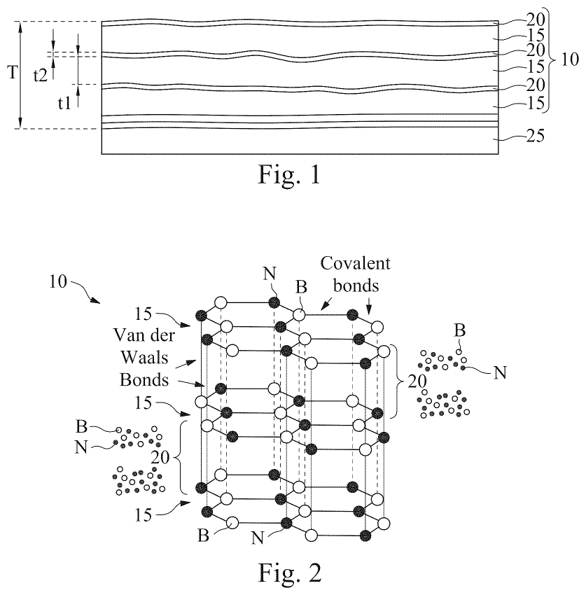

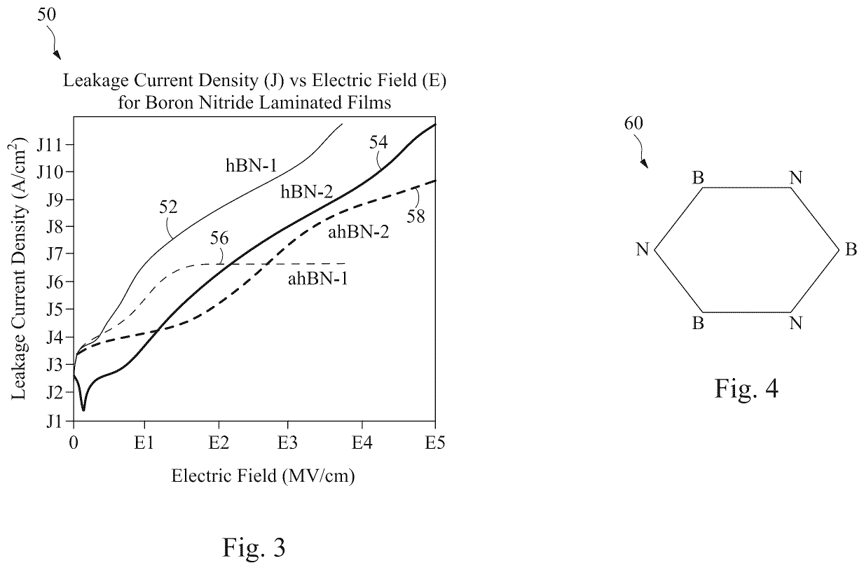

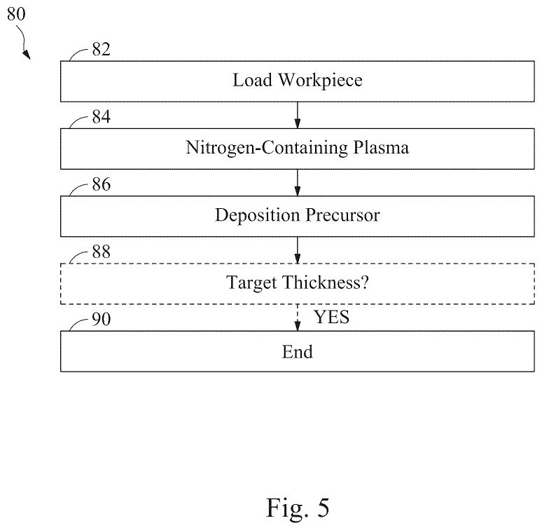

FIG. 1 depicts a laminated dielectric film 10, in portion or entirety, according to various aspects of the present disclosure. FIG. 2 is a schematic diagram of laminated dielectric film 10, in portion or entirety, according to some embodiments of the present disclosure. FIG. 3 provides experimental current-voltage characteristics for different laminated dielectric films, according to various aspects of the present disclosure. FIG. 4 depicts a deposition precursor 60 that may be used to form laminated dielectric film 10, according to some embodiments of the present disclosure. FIG. 5 depicts a method, in portion or entirety, of forming a laminated dielectric film, such as laminated dielectric film 10, according to some embodiments of the present disclosure. Laminated dielectric film 10 may also be referred to as a laminated dielectric layer, a laminate dielectric structure, a laminate insulating structure, a laminate insulating film (and/or layer), and the like. FIGS. 1-5 are discussed concurrently herein for ease of description and understanding. FIGS. 1-5 have been simplified for the sake of clarity to better understand the inventive concepts of the present disclosure. Additional features may be added in laminated dielectric film 10, and some of the features described below may be replaced, modified, or eliminated in other embodiments of laminated dielectric film 10.

Referring to FIG. 1, laminated dielectric film 10 includes at least two dielectric layers having different crystalline characteristics and/or different crystalline conditions, such as a first dielectric layer and a second dielectric layer having different crystalline characteristics. For example, the first dielectric layer is formed of a first dielectric material having a crystalline structure (e.g., the first dielectric material is in crystalline form (i.e., having an ordered atomic structure)) and the second dielectric layer is formed of a second dielectric material having an amorphous structure (e.g., the second dielectric material is in non-crystalline form (i.e., having a disordered atomic structure)). In some embodiments, the first dielectric material and the second dielectric material are the same dielectric material formed to have different atom/particle arrangements to provide a laminate structure. In some embodiments, the first dielectric material and the second dielectric material are different dielectric materials.

In the depicted embodiment, laminated dielectric film 10 includes crystalline boron nitride layers 15 and amorphous boron nitride layers 20 stacked in an alternating and/or interleaving configuration. For example, in FIG. 1, laminated dielectric film 10 includes three crystalline boron nitride layers 15 and three amorphous boron nitride layers 20, where a first one of amorphous boron nitride layers 20 is sandwiched between two respective crystalline boron nitride layers 15 and a second one of amorphous boron nitride layers 20 is sandwiched between two respective crystalline boron nitride layers 15. In the depicted embodiment, a third one of amorphous boron nitride layers 20 is formed over a respective crystalline boron nitride layer 15 and forms a top of laminated dielectric film 10. In some embodiments, a respective crystalline boron nitride layer 15 may form a top of laminated dielectric film 10. In some embodiments, crystalline boron nitride layers 15 are hexagonal boron nitride (hBN) layers, and amorphous boron nitride layers 20 interleaved between crystalline boron nitride layers 15. In such embodiments, referring to FIG. 2, each of crystalline boron nitride layers 15 may include boron (B) atoms and nitrogen (N) atoms arranged in an ordered, hexagonal pattern, and each of amorphous boron nitride layers 20 may include boron (B) atoms and nitrogen (N) atoms arranged in a disordered manner (i.e., not in a pattern). In some embodiments, the boron atoms and the nitrogen atoms of crystalline boron nitride layers 15 are covalently bonded. For example, each boron atom may be covalently bonded to three nitrogen atoms in a manner that provides crystalline boron nitride layers 15 with a lattice structure that includes hexagonal rings. In contrast, in some embodiments, the boron atoms and the nitrogen atoms of amorphous boron nitride layers 20 are cohered and/or held together by Van der Waals forces. In such example, the weaker Van der Waals forces between the boron atoms and the nitrogen atoms may provide amorphous boron nitride layers 20 with a disordered lattice structure.

The present disclosure incorporates amorphous dielectric layers (e.g., amorphous boron nitride layers 20) into laminated dielectric films formed of crystalline dielectric layers (e.g., laminated dielectric film 10 formed of crystalline boron nitride layers 15) to reduce leakage current, which may undesirably flow in dielectric materials and degrade performance of semiconductor devices. Referring to FIG. 3, a plot 50 provides experimental current-voltage (I-V) characteristics for different laminated dielectric structures according to various aspects of the present disclosure. For example, plot 50 depicts experimental leakage current densities (J) in amps per centimeter squared (A/cm²) as a function of electric field in megavolts per centimeter (MV/cm) under an applied voltage for different laminated boron nitride films. In plot 50, a line 52 corresponds with observed leakage current densities of a laminated crystalline boron nitride film of a first thickness (e.g., about 40 nm); line 54 corresponds with observed leakage current densities of a laminated crystalline boron nitride film of a second thickness (e.g., about 16 nm); line 56 corresponds with observed leakage current densities of a laminated amorphous/crystalline boron nitride film, such as laminated dielectric film 10, of the first thickness; and line 58 corresponds with observed leakage current densities of a laminated amorphous/crystalline boron nitride film, such as laminated dielectric film 10, of the second thickness. In some embodiments, the laminated crystalline boron nitride films are respective stacks of hexagonal boron nitride layers (e.g., hBN-1 and hBN-2) having the first thickness and the second thickness, respectively, and the laminated amorphous/crystalline boron nitride films are respective stacks of hexagonal boron nitride layers interleaved with amorphous boron nitride layers (e.g., ahBN-1 and ahBN-2) having the first thickness and the second thickness, respectively, such as described herein.

Leakage current densities of about J1 to about J11 (e.g., about 1×10⁻¹¹ A/cm ² to about 1×10⁻¹ A/cm²) are observed for the laminated boron nitride films as applied electric field increases from about 0 MV/cm to E5. For example, leakage current density for thicker laminated crystalline boron nitride film (hBN-1) increases from about J3 to about J11 as applied voltage increases from 0 to E4; leakage current density for thinner laminated crystalline boron nitride film (hBN-2) increases from about J2 to greater than J11 as applied voltage increases from 0 to E5; leakage current density for thicker laminated amorphous/crystalline boron nitride film (ahBN-1) increases from about J3 to about J6 as applied voltage increases from 0 to E4; and leakage current density for thinner laminated amorphous/crystalline boron nitride film (ahBN-2) increases from about J3 to greater than J9 as applied voltage increases from 0 to E5. From FIG. 3, it is observed that leakage current density of thicker laminated amorphous/crystalline boron nitride film (ahBN-1) is less than leakage current density of thicker laminated crystalline boron nitride film (hBN-1), and leakage current density of thinner laminated amorphous/crystalline boron nitride film (ahBN-2) is less than leakage current density of thinner laminated crystalline boron nitride film (hBN-2) (e.g., at least for applied voltages greater than about E1). Further, leakage current density of thicker laminated amorphous/crystalline boron nitride film (ahBN-1) appears to plateau for applied voltages greater than about E2. In other words, advantageously, leakage current density of thicker laminated amorphous/crystalline boron nitride film (ahBN-1) does not appear to increase upon reaching a threshold applied voltage.

Based on these experimental results, since amorphous boron nitride layers (e.g., amorphous boron nitride layers 20) reduce leakage current, amorphous boron nitride layers may be incorporated into laminated dielectric films formed of crystalline dielectric layers (e.g., laminated dielectric film 10 formed of crystalline boron nitride layers 15) to mitigate higher leakage currents of crystalline boron nitride layers, thereby improving semiconductor device performance. For example, a laminated amorphous/crystalline boron nitride film may provide a semiconductor device (e.g., a transistor) with a chemically stable, low dielectric constant dielectric layer (such as provided by the crystalline boron nitride layers, which may exhibit a dielectric constant of about 3 and remain chemically stable when subjected to high process and/or high operation temperatures) that exhibits reduced leakage current (such as provided by the amorphous boron nitride layers, which may block current leakage paths, such as vertical leakage paths). In some embodiments, leakage current reduction of greater than one order may be provided by amorphous boron nitride layers. Different embodiments may have different advantages, and no particular advantage is required of any embodiment.

Referring again to FIG. 1, thicknesses of crystalline boron nitride layers 15 and thicknesses of amorphous boron nitride layers 20 (which interleave crystalline boron nitride layers 15) are configured to provide laminated dielectric film 10 as an electrically insulating, thermally conductive layer that exhibits reduced leakage current. In FIG. 1, laminated dielectric film 10 has a thickness T, crystalline boron nitride layers 15 have a thickness t1, and amorphous boron nitride layers 20 have a thickness t2. In some embodiments, such as depicted, thickness t1 is greater than thickness t2, for example, to provide laminated dielectric film 10 with a thermal conductivity that is sufficiently high enough to effectively dissipate heat. For example, crystalline boron nitride layers 15 (e.g., h-BN layers) may exhibit an in-plane thermal conductivity above 390 W/m·K at room temperature, while amorphous boron nitride layers 20 (e.g., a-BN layers) may exhibit an in-plane thermal conductivity around 3 W/m·K, which is not considered as a thermally conductive material in the context of the present disclosure. In some embodiments, thickness t1 and thickness t2 are configured to provide laminated dielectric film 10 with a thermal conductivity that is at least 10 W/m·K. Thermal conductivity that is less than about 10 W/m·K may not effectively dissipate heat. In some embodiment, thickness T is about 15 nm to about 45 nm. In some embodiment, thickness t1 is about 0.5 nm to about 2 nm. In some embodiment, thickness t2 is about 0.5 nm to about 5 nm. In some embodiments, a sum of thicknesses of crystalline boron nitride layers 15 is less than a sum of thicknesses of amorphous boron nitride layers 20. Though crystalline boron nitride layers 15 have substantially the same thickness (e.g., thickness t1) and amorphous boron nitride layers 20 have substantially the same thickness (e.g., thickness t2) in the depicted embodiment, the present disclosure contemplates embodiments where crystalline boron nitride layers 15 may have different thicknesses and/or amorphous boron nitride layers 20 may have different thicknesses. The present disclosure further contemplates embodiments where thickness t1 may be less than thickness t2.

In some embodiments, laminated dielectric film 10 has a dielectric constant of about 1.8 to about 8.6 (1.8≤k≤8.6). For example, laminated dielectric film 10 has a dielectric constant of about 3 (k≈3). A dielectric constant of crystalline boron nitride layers 15 is greater than a dielectric constant of amorphous boron nitride layers 20. Inserting amorphous boron nitride layers 20 into laminated dielectric film 10 may thus reduce its dielectric constant. In some embodiments, crystalline boron nitride layers 15 have a dielectric constant of about 3.0 to about 5.0 (3.0≤k≤5.0). In some embodiments, amorphous boron nitride layers 20 have a dielectric constant of about 1.5 to about 3.0 (1.5≤k≤3.0).

Laminated dielectric film 10 may be formed by a deposition process, such as chemical vapor deposition (CVD), where various deposition parameters are tuned to provide laminated dielectric film 10 with at least one crystalline boron nitride layer and at least one amorphous boron nitride layer. In some embodiments, the deposition process is tuned to provide laminated dielectric film 10 with a stack of crystalline boron nitride layers interleaved with amorphous boron nitride layers, such as describe herein. The various deposition parameters may include deposition precursor(s) (including reactant gas(es)), deposition time(s), deposition temperature(s), deposition pressure(s), other deposition parameters, or combinations thereof. In some embodiments, laminated dielectric film 10 is deposited and/or grown directly on a base layer 25 (e.g., a substrate, a material layer, a device layer, and/or a device feature) of a semiconductor device (e.g., transistor) during fabrication thereof. In some embodiments, laminated dielectric film 10 is deposited and/or grown on a carrier substrate (and/or layer) and then transferred to a semiconductor device (e.g., transistor) during fabrication thereof.

Referring to FIG. 5, FIG. 5 depicts a flow chart of a deposition process 80 that may be implemented to form laminated dielectric film 10, according to some embodiments. Deposition process 80 may be a plasma-enhanced CVD process, and deposition process 80 facilitates deposition and/or growth of laminated dielectric film 10 directly on a semiconductor device during fabrication thereof. At block 82, a workpiece upon which laminated dielectric film 10 is to be deposited/grown is loaded into a process chamber. In some embodiments, the workpiece may include a semiconductor device (e.g., a transistor), or portion thereof, on and/or over which deposition process 80 is to form the laminated dielectric film.

Deposition process 80 may include generating a nitrogen-containing plasma into the process chamber at block 84 and flowing a boron-and-nitrogen containing deposition precursor into the process chamber at block 86. The present disclosure contemplates block 84 being performed before, after, or at the same time as block 86. In some embodiments, the boron-and-nitrogen containing deposition precursor is borazine (e.g., B₃N₃H₆). In some embodiments, the boron-and-nitrogen containing deposition precursor has a hexagonal ring structure, such as depicted in FIG. 4. The hexagonal ring structure may be bonded to terminal groups, which may be organic or inorganic. In some embodiments, the boron-and-nitrogen containing deposition precursor is an organic deposition precursor, which may include the hexagonal ring structure. In some embodiments, the boron-and-nitrogen containing deposition precursor is an inorganic deposition precursor, which may include the hexagonal ring structure. The nitrogen-containing plasma may be generated from a nitrogen-containing precursor gas that includes diatomic nitrogen (N₂), ammonia (NH₃), other suitable nitrogen-containing precursor gas, or combinations thereof. The nitrogen-containing plasma may thus be an N₂ plasma, an NH₃ plasma, or an N₂/NH₃ plasma, and the nitrogen-containing plasma includes nitrogen-containing excited neutral molecules (for example, N₂*), nitrogen-containing ionized molecules (for example, N₂+), nitrogen-containing atoms (for example, N), ionized atoms (N+), or combinations thereof (all generally referred to as plasma-excited nitrogen-containing species).

Various parameters of deposition process 80 are tuned to provide the laminated dielectric film with at least one crystalline boron nitride layer and at least one amorphous boron nitride layer. The parameters include deposition precursor(s) (including reactant gas(es) and/or carrier gas(es)), flow rate of the deposition precursor(s), flow rate of the reactant gas(es), flow rate of the carrier gas(es), deposition time(s), deposition temperature(s), deposition pressure(s), other deposition parameters (e.g., a power and/or a voltage used to generate the nitrogen-containing plasma), or combinations thereof. In some embodiments, deposition process 80 implements a deposition temperature of about 200° C. to about 400° C. For example, a temperature maintained in the process chamber during deposition process 80 may be about 200° C. to about 400° C. In another example, the workpiece is heated to a temperature of about 200° C. to about 400° C. during deposition process 80. In some embodiments, deposition process 80 switches between two sets of deposition parameters to alternately deposit crystalline boron nitride layers and amorphous boron nitride layers. For example, one set of deposition parameters may be implemented to form crystalline boron nitride layers, and a second set of deposition parameters may be implemented to form amorphous boron nitride layers. In some embodiments, deposition process 80 dynamically adjusts a flow rate of the boron-and-nitrogen containing deposition precursor gas and/or a flow rate of the nitrogen-containing precursor gas to alternately deposit crystalline boron nitride layers and amorphous boron nitride layer. In some embodiments, deposition process 80 dynamically adjusts deposition temperature, deposition pressure, deposition time, other deposition parameters (e.g., a power and/or a voltage used to generate the nitrogen-containing plasma), or combinations thereof to alternately deposit crystalline boron nitride layers and amorphous boron nitride layer.

In some embodiments, deposition process 80 may include determining whether a laminated dielectric film, as deposited, has a target thickness at block 88. If the laminated dielectric film has the target thickness, deposition process 80 may end at block 90. If not, in some embodiments, block 84 and/or block 86 may continue and/or be repeated until reaching the target thickness. Deposition process 80 is also configured to minimize oxygen exposure (e.g., by depositing the laminated dielectric films under vacuum conditions), such that laminated dielectric films resulting therefrom, such as laminated dielectric film 10, exhibit desired oxidation resistance. For example, the as-deposited laminated dielectric films exhibit sufficiently low oxygen concentrations, and any oxygen present in the as-deposited laminated dielectric films may be from an oxygen ambient (e.g., air), which the as-deposited dielectric films may be exposed to during processing, such as when transferred between process chambers. In some embodiments, the laminated dielectric films, such as laminated dielectric film 10, have an oxygen concentration less than about 4%. Oxygen concentrations greater than about 4% may undesirably increase dielectric constants, increase leakage current, reduce thermal conductivity, reduce chemical stability, or combinations thereof of the laminated dielectric films. Additional steps may be provided before, during, and after method 80, and some of the steps described may be moved, replaced, or eliminated for additional embodiments of method 80.

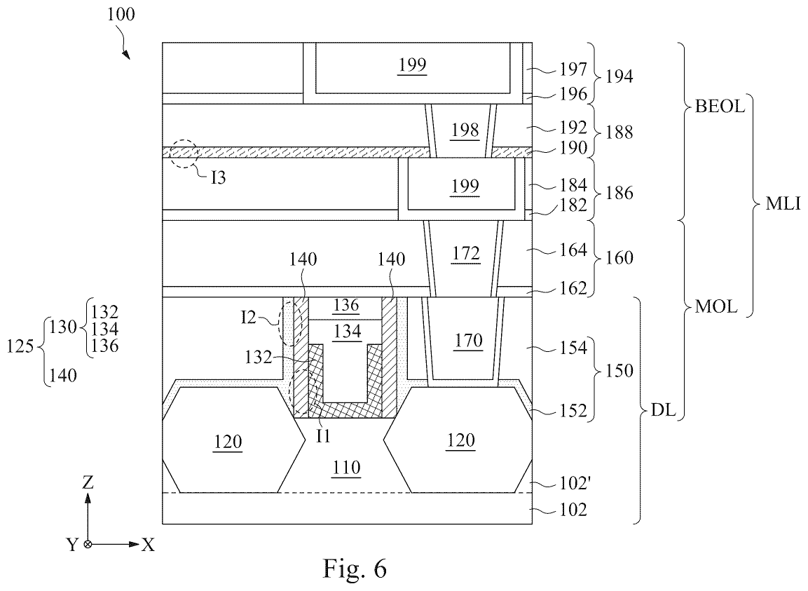

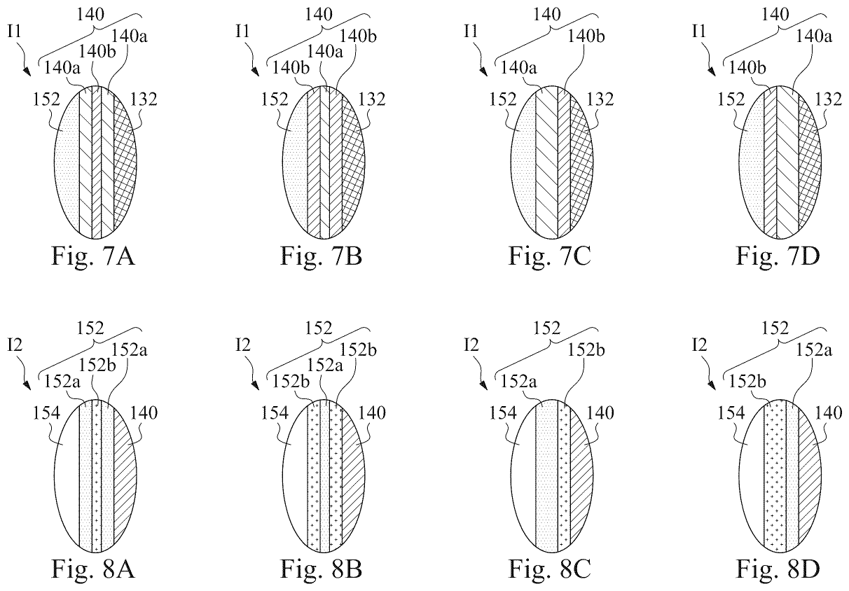

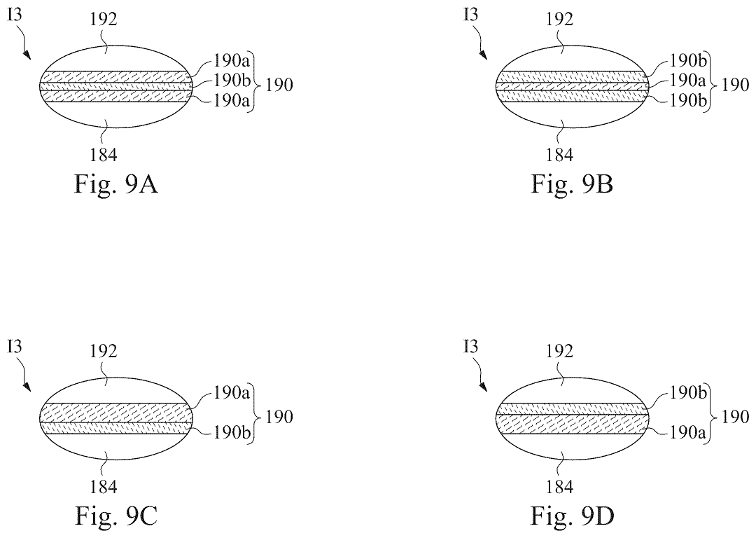

FIG. 6 is a cross-sectional view of a transistor 100, in portion or entirety, that may incorporate a laminated dielectric film, such as laminated dielectric film 10 described with reference to FIGS. 1-5 and/or other laminated dielectric films described herein, according to various aspects of the present disclosure. FIGS. 7A-7D are enlarged views, in portion or entirety, of different configurations of a portion I1 of transistor 100 that may incorporate a laminated dielectric film, according to various aspects of the present disclosure. FIGS. 8A-8D are enlarged views, in portion or entirety, of different configurations of a portion I2 of transistor 100 that may incorporate a laminated dielectric film, according to various aspects of the present disclosure. FIGS. 9A-9D are enlarged views, in portion or entirety, of different configurations of a portion I3 of an interconnect structure that may be connected to transistor 100 and that may incorporate a laminated dielectric film, according to various aspects of the present disclosure. FIG. 6, FIGS. 7A-7D, FIGS. 8A-8D, and FIGS. 9A-9D are discussed concurrently herein for ease of description and understanding. FIG. 6, FIGS. 7A-7D, FIGS. 8A-8D, and FIGS. 9A-9D have been simplified for the sake of clarity to better understand the inventive concepts of the present disclosure. Additional features may be added in transistor 100 and/or the interconnect structure, and some of the features described below may be replaced, modified, or eliminated in other embodiments of transistor 100 and/or the interconnect structure.

Referring to FIG. 6, transistor 100 may be formed over and/or include a substrate 102. In the depicted embodiment, substrate 102 is a silicon substrate. Substrate 102 may include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 102 is a semiconductor-on-insulator substrate, such as a silicon-on-insulator (SOI) substrate, a silicon germanium-on-insulator (SGOI) substrate, or a germanium-on-insulator (GOI) substrate. Substrate 102 may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, other p-type dopant, or combinations thereof.

Transistor 100 includes an active region, which includes a channel 110 and source/drains 120, which may be formed and/or disposed in substrate 102. In FIG. 6, source/drains 120 are disposed in substrate 102, and channel 110 is formed in a portion of substrate 102 disposed between source/drains 120. The active region may be oriented lengthwise along an x-direction (i.e., length is along the x-direction, width is along a y-direction, and height is along a z-direction). In some embodiments, such as where transistor 100 is a fin-like field effect transistor (FinFET), the active region of transistor 100 may include a fin structure 102′ extending from substrate 102, source/drains 120 may be formed in fin structure 102′, and channel 110 may be formed in a portion of fin structure 102′ that is disposed between source/drains 120. Fin structure 102′ extends along the x-direction, having a length along the x-direction, a width along a y-direction, and a height along a z-direction. In some embodiments, fin structure 102′ is a semiconductor fin that includes silicon, germanium, silicon germanium, other suitable semiconductor material, or combinations thereof. In some embodiments, fin structure 102′ is formed from a portion of substrate 102. For example, substrate 102 may be a silicon substrate, and fin structure 102′ may be a patterned portion and/or extension of substrate 102 (i.e., a silicon fin). In some embodiments, fin structure 102′ is formed from one or more semiconductor layers deposited and patterned over substrate 102. For example, substrate 102 may be a silicon substrate, and fin structure 102′ may be formed from a silicon germanium layer deposited and patterned over substrate 102 (i.e., a silicon germanium fin). In some embodiments, a composition and/or a material of fin structure 102′ based on a type of transistor 100 (e.g., whether transistor 100 is a p-type FinFET or an n-type FinFET).

Source/drains 120 include a semiconductor material, source/drains 120 may be doped with n-type dopants and/or p-type dopants, and source/drains 120 may have the same or different compositions and/or materials. In some embodiments, the semiconductor material(s) of source/drains 120 are formed by an epitaxy process, source/drains 120 are formed of epitaxially grown/deposited semiconductor material, and source/drains 120 may be referred to as epitaxial source/drains. In some embodiments (e.g., when forming portions of n-type transistors), source/drains 120 may include silicon doped with carbon, phosphorous, arsenic, other n-type dopant, or combinations thereof. In some embodiments (e.g., when forming portions of p-type transistors), source/drains 120 may include silicon germanium or germanium doped with boron, other p-type dopant, or combinations thereof. In some embodiments, doped regions, such as heavily doped source/drain (HDD) regions, lightly doped source/drain (LDD) regions, other doped regions, or combinations thereof, are disposed in source/drains 120. In some embodiments, the doped regions, such as LDD regions, may extend into channel 110. As used herein, source/drain region, source/drain, source/drain structure, epitaxial source/drain, epitaxial source/drain feature, etc. may refer to a source of transistor 100, a drain of transistor 100, or a source and/or a drain of multiple devices (including transistor 100).

Transistor 100 further includes a gate structure 125, which includes at least a gate stack 130. Gate stack 130 (also referred to as a high-k/metal gate, in some embodiments) is disposed on and engages channel 110, and gate stack 130 is disposed between source/drains 120. Gate stack 130 may extend lengthwise in a direction that is different than (e.g., orthogonal to) the lengthwise direction of the active region (e.g., a direction along which channel 110 and source/drains 120 are arranged relative to one another). For example, gate stack 130 extends lengthwise along the y-direction, having a length along the y-direction, a width along the x-direction, and a height along the z-direction. In a cross-sectional view along a lengthwise direction of the active region (FIG. 6), gate stack 130 is disposed on a top of channel 110. In a cross-sectional view along a widthwise direction of the active region (e.g., along the y-direction), gate stack 130 is also disposed over a top of channel 110. In some embodiments, such as where active region of transistor 100 is provided by a fin structure (i.e., transistor 100 is a FinFET), gate stack 130 may be disposed on sidewalls of channel 110 in the cross-sectional view along the widthwise direction of the active region, and gate stack 130 may wrap channel 110.

Gate stack 130 may include a gate dielectric 132 and a gate electrode 134. Gate dielectric 132 is disposed on channel 110. Gate dielectric 132 includes at least one dielectric layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃, (Ba,Sr)TiO₃ (BST), HfO₂-Al₂O₃, other high-k dielectric material, or combinations thereof. In some embodiments, the high-k dielectric layer includes a hafnium oxide (e.g., HfO₂) layer and/or a zirconium oxide (e.g., ZrO₂) layer.

Gate electrode 134 is disposed on gate dielectric 132. Gate electrode 134 includes an electrically conductive layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive layer includes a work function layer tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

In some embodiments, gate stack 130 includes a hard mask 136 (e.g., a self-aligned cap (SAC) structure). Hard mask 136 is disposed on gate electrode 134, and hard mask 136 may be disposed on gate dielectric 132. Hard mask 136 includes a material that is different than subsequently formed dielectric layers to achieve etch selectivity. In some embodiments, hard mask 136 includes silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard mask 136 includes metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof.

Gate structure 125 further includes gate spacers 140. Gate spacers 140 are disposed adjacent to and along sidewalls of gate stack 130. In the depicted embodiment, the sidewalls of gate stack 130 are formed by gate dielectric 132, gate electrode 134, and hard mask 136, and gate spacers 140 abut gate dielectric 132, gate electrode 134, and hard mask 136. In other embodiments, gate dielectric 132 and hard mask 136, but not gate electrode 134, may form the sidewalls of gate stack 130, such that gate spacers 140 may abut gate dielectric 132 and hard mask 136, but not gate electrode 134. Various configurations of gate stack 130 and gate spacers 140 relative thereto are contemplated by the disclosure. Gate spacers 140 include a dielectric material, which may include silicon, oxygen, carbon, nitrogen, other suitable constituent (e.g., boron), or combinations thereof (e.g., silicon nitride, silicon oxynitride, silicon carbide, silicon carbonitride, silicon oxycarbide, silicon oxycarbonitride, boron nitride, etc.).

In some embodiments, gate spacers 140 have boron-and-nitrogen containing laminate structures. The boron-and-nitrogen containing laminate structures include at least one crystalline boron nitride layer 140a, such as a hexagonal boron nitride layer, and at least one amorphous boron nitride layer 140b (see FIGS. 7A-7D). Crystalline boron nitride layer 140a is similar to crystalline boron nitride layers described herein, such as crystalline boron nitride layers 15, and amorphous boron nitride layer 140b is similar to amorphous boron nitride layers described herein, such as amorphous boron nitride layers 20. In some embodiments, gate spacers 140 having the boron-and-nitrogen containing laminate structures have a dielectric constant of about 1.8 to about 8.6 (1.8≤k≤8.6), such as a dielectric constant of about 3 (k≈3).

The boron-and-nitrogen containing laminate structure of gate spacers 140 may have various configurations, such as those depicted in FIGS. 7A-7D. For example, referring to FIG. 7A, the boron-and-nitrogen containing laminate structure of gate spacers 140 may include an amorphous boron nitride layer 140b disposed between crystalline boron nitride layers 140a. In such example, crystalline boron nitride layers 140a abut gate stack 130 (e.g., gate dielectric 132 and/or gate electrode 134 thereof) and a dielectric layer 150 adjacent to gate spacers 140, such as a contact etch stop layer (CESL) 152 of dielectric layer 150. In another example, referring to FIG. 7B, the boron-and-nitrogen containing laminate structure of gate spacers 140 may include a crystalline boron nitride layer 140a disposed between amorphous boron nitride layers 140b. In such example, amorphous boron nitride layers 140b abut gate stack 130 and dielectric layer 150 (e.g., CESL 152 thereof). In yet another example, referring to FIG. 7C and FIG. 7D, the boron-and-nitrogen containing laminate structure of gate spacers 140 may include a single crystalline boron nitride layer 140a and a single amorphous boron nitride layer 140b. In some embodiments of this example, amorphous boron nitride layer 140b may abut gate stack 130, while crystalline boron nitride layer 140a abuts dielectric layer 150 (e.g., CESL 152 thereof), such as depicted in FIG. 7C. In other embodiments of this example, crystalline boron nitride layer 140a may abut gate stack 130, while amorphous boron nitride layer 140b abuts dielectric layer 150 (e.g., CESL 152 thereof), such as depicted in FIG. 7D. In yet another example, the boron-and-nitrogen containing laminate structure of gate spacers 140 may include multiple crystalline boron nitride layers 140a interleaved with amorphous boron nitride layers 140b. For example, the boron-and-nitrogen containing laminate structure may be configured as laminated dielectric film 10.

Dielectric layer 150 is disposed over substrate 102, source/drains 120, and gate structure 125 (e.g., gate stack 130 and gate spacers 140). Dielectric layer 150 may have a multilayer structure, such as CESL 152 and an interlayer dielectric (ILD) layer 154. ILD layer 154 is disposed over CESL 152. ILD layer 154 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 154 includes a dielectric material having a dielectric constant that is less than a dielectric constant of silicon dioxide (e.g., k<3.9). In some embodiments, ILD layer 154 includes a dielectric material having a dielectric constant that is less than about 2.5, such as porous silicon oxide, silicon carbide, carbon-doped oxide (e.g., SiCOH-based material), or combinations thereof. CESL 152 includes a dielectric material that is different than the dielectric material of ILD layer 154. For example, where ILD layer 154 includes silicon and oxygen (e.g., porous silicon oxide), CESL 152 may include silicon and nitrogen, and CESL 152 may be a silicon nitride layer, a silicon carbonitride layer, or a silicon oxycarbonitride layer.

In some embodiments, a dielectric constant of CESL 152 is greater than a dielectric constant of ILD layer 154. In some embodiments, a dielectric constant of CESL 152 is less than a dielectric constant of gate dielectric 132. In some embodiments, a dielectric constant of ILD layer 154 is less than a dielectric constant of gate dielectric 132. In some embodiments, a dielectric constant of gate dielectric 132 is at least two times a dielectric constant of ILD layer 154. In some embodiments, a dielectric constant of ILD layer 154 is about 3 to about 5. In some embodiments, a dielectric constant of the boron-and-nitrogen containing laminate structure of gate spacers 140 (and/or other features implementing the disclosed laminate structures) is less than a dielectric constant of ILD layer 154. In some embodiments, a dielectric constant of the boron-and-nitrogen containing laminate structure of gate spacers 140 (and/or other features implementing the disclosed laminate structures) is less than a dielectric constant of CESL 152. In some embodiments, a dielectric constant of the boron-and-nitrogen containing laminate structure of gate spacers 140 (and/or other features implementing the disclosed laminate structures) is less than a dielectric constant of gate dielectric 132. In some embodiments, a dielectric constant of gate dielectric 132 is greater than a dielectric constant of gate spacers 140, CESL 152, and ILD layer 154. In such embodiments, a dielectric constant of CESL 152 may be greater than a dielectric constant of gate spacers 140 and/or a dielectric constant of ILD layer 154, and a dielectric constant of gate spacers 140 may be greater than, less than, or about the same as a dielectric constant of ILD layer 154.

In some embodiments, CESL 152 has a boron-and-nitrogen containing laminate structure. The boron-and-nitrogen containing laminate structure includes at least one crystalline boron nitride layer 152a, such as a hexagonal boron nitride layer, and at least one amorphous boron nitride layer 152b (see FIGS. 8A-8D). Crystalline boron nitride layer 152a is similar to crystalline boron nitride layers described herein, such as crystalline boron nitride layers 15, and amorphous boron nitride layer 152b is similar to amorphous boron nitride layers described herein, such as amorphous boron nitride layers 20. In some embodiments, CESL 152 having the boron-and-nitrogen containing laminate structure has a dielectric constant of about 1.8 to about 8.6 (1.8≤k≤8.6), such as a dielectric constant of about 3 (k≈3).

The boron-and-nitrogen containing laminate structure of CESL 152 may have various configurations, such as those depicted in FIGS. 8A-8D. For example, referring to FIG. 8A, the boron-and-nitrogen containing laminate structure of CESL 152 may include an amorphous boron nitride layer 152b disposed between crystalline boron nitride layers 152a. In such example, crystalline boron nitride layers 152a abut gate spacers 140 and ILD layer 154, and crystalline boron nitride layers 152a (e.g., of a portion of CESL 152 disposed over source/drains 120) may abut source/drains 120. In another example, referring to FIG. 8B, the boron-and-nitrogen containing laminate structure of CESL 152 may include a crystalline boron nitride layer 152a disposed between amorphous boron nitride layers 152b. In such example, amorphous boron nitride layers 152b abut gate spacers 140 and ILD layer 154, and amorphous boron nitride layers 152b (e.g., of a portion of CESL 152 disposed over source/drains 120) may abut source/drains 120. In yet another example, referring to FIG. 8C and FIG. 8D, the boron-and-nitrogen containing laminate structure of CESL 152 may include a single crystalline boron nitride layer 152a and a single amorphous boron nitride layer 152b. In some embodiments of this example, amorphous boron nitride layer 152b may abut gate spacers 140, while crystalline boron nitride layer 152a abuts ILD layer 154, such as depicted in FIG. 8C. In other embodiments of this example, crystalline boron nitride layer 152a may abut gate spacers 140, while amorphous boron nitride layer 152b abuts ILD layer 154, such as depicted in FIG. 8D. In yet another example, the boron-and-nitrogen containing laminate structure of CESL 152 may include multiple crystalline boron nitride layers 152a interleaved with amorphous boron nitride layers 152b. For example, the laminate structure of CESL 152 may be configured as laminated dielectric film 10.

Transistor 100 may further include a multilayer interconnect (MLI) structure over substrate 102, such as over a frontside thereof. MLI structure may include a back-end-of-line (BEOL structure) and/or a middle-of-line (MOL) structure. MLI structure includes dielectric layers and electrically conductive layers (e.g., patterned metal layers, each of which may be a group of metal lines, metal vias, metal contacts, or combinations thereof arranged in a desired pattern) that combine to form interconnect (routing) structures. In some embodiments, the dielectric layers of MLI structure include a dielectric layer 160, which may have a multilayer structure (e.g., a CESL 162 and an ILD layer 164), a dielectric layer 186, which may have a multilayer structure (e.g., a CESL 182 and an ILD layer 184), a dielectric layer 188, which may have a multilayer structure (e.g., a CESL 190 and an ILD layer 192), and a dielectric layer 194, which may have a multilayer structure (e.g., a CESL 196 and an ILD layer 197). CESL 162, CESL 182, CESL 190, CESL 196, or combinations thereof may be configured similar to CESL 152. ILD layer 164, ILD layer 184, ILD layer 192, ILD layer 197, or combinations thereof may be configured similar to ILD layer 154. The interconnect structures may include vertically oriented electrically conductive features, such as metal contacts and/or metal vias, that connect horizontally oriented electrically conductive features, such as metal lines, in different layers/levels (or different planes) of the MLI structure. In some embodiments, the routing structures of MLI structure route electrical signals between devices and/or components of device layer DL, MLI structure, external devices and/or components, or combinations thereof. In some embodiments, MLI structure distributes electrical signals (e.g., clock signals, voltage signals, ground signals, etc.) to transistor 100, other devices/components of a chip to which transistor 100 may belong, external devices and/or components, or combinations thereof.

MLI structure includes a device-level contact layer and/or via layer (collectively referred to as a via zero layer (V0 level)) (which may include device-level contacts, such as a source/drain contact 170, and/or device-level vias, such as a source/drain via 172), a metal zero layer (M0 level), a via one layer (V1 level), a metal one layer (M1 level), a via two layer (V2 level), a metal two layer (M2 level), and so on to a via (X-1) layer (V(X-1) level), a metal (X-1) layer (M(X-1) level), a via X layer (VX level), and a metal X layer (MX level), where X is an integer (e.g., from 2 to 10). Each level of MLI structure may include conductive features, such as metal lines 199 or metal vias 198, disposed in a respective dielectric layer (e.g., dielectric layer 186, dielectric layer 188, and/or dielectric layer 194). Metal lines 199 of M0 level, M1 level, M2 level, . . . M(X-1) level, and MX level may be referred to as M0 lines, M1 lines, M2 lines, . . . M(X-1) lines, and MX lines, respectively. Metal vias 198 of V0 level, V1 level, V2 level, . . . V(X-1) level, and VX level may be referred to as V0 vias, V1 vias, V2 vias, . . . V(X-1) vias, and VX vias, respectively. Each metal via 198 may physically and/or electrically connect an underlying metal line 199 (e.g., a respective M1 line) and an overlying metal line 199 (e.g., a respective M2 line), an underlying device-level contact (e.g., a source/drain contact) and an overlying metal line 199 (e.g., a respective M0 line), or an underlying device feature (e.g., a gate and/or a source/drain) and an overlying metal line 199 (e.g., a respective M0 line).

In some embodiments, one or more CESLs of MLI structure, such as CESL 190, has a boron-and-nitrogen containing laminate structure. The boron-and-nitrogen containing laminate structure includes at least one crystalline boron nitride layer (e.g., crystalline boron nitride layer 190a), such as a hexagonal boron nitride layer, and at least one amorphous boron nitride layer (e.g., amorphous boron nitride layer 190b) (see FIGS. 9A-9D). Crystalline boron nitride layer 190a is similar to crystalline boron nitride layers described herein, such as crystalline boron nitride layers 15, and amorphous boron nitride layer 190b is similar to amorphous boron nitride layers described herein, such as amorphous boron nitride layers 20. In some embodiments, a CESL, such as CESL 190, having the boron-and-nitrogen containing laminate structure has a dielectric constant of about 1.8 to about 8.6 (1.8≤k≤8.6), such as about 3 (k≈3).

The boron-and-nitrogen containing laminate structure of CESL 190 may have various configurations, such as those depicted in FIGS. 9A-9D. For example, referring to FIG. 9A, the boron-and-nitrogen containing laminate structure of CESL 190 may include an amorphous boron nitride layer 190b disposed between crystalline boron nitride layers 190a. In such example, crystalline boron nitride layers 190a may abut ILD layers (e.g., ILD layer 184 and ILD layer 192). In another example, referring to FIG. 9B, the boron-and-nitrogen containing laminate structure of CESL 190 may include a crystalline boron nitride layer 190a disposed between amorphous boron nitride layers 190b. In such example, amorphous boron nitride layers 190b may abut ILD layers (e.g., ILD layer 184 and ILD layer 192). In yet another example, referring to FIG. 9C and FIG. 9D, the boron-and-nitrogen containing laminate structure of CESL 190 may include a single crystalline boron nitride layer 190a and a single amorphous boron nitride layer 190b. In some embodiments of this example, amorphous boron nitride layer 190b may abut ILD layer 184, while crystalline boron nitride layer 190a abuts ILD layer 192, such as depicted in FIG. 9C. In other embodiments of this example, crystalline boron nitride layer 190a may abut ILD layer 184, while amorphous boron nitride layer 190b abuts ILD layer 192, such as depicted in FIG. 9D. In yet another example, the boron-and-nitrogen containing laminate structure of CESL 190 may include multiple crystalline boron nitride layers 190a interleaved with amorphous boron nitride layers 190b. In such example, the boron-and-nitrogen containing laminate structure of CESL 190 may be configured as laminated dielectric film 10 described herein.

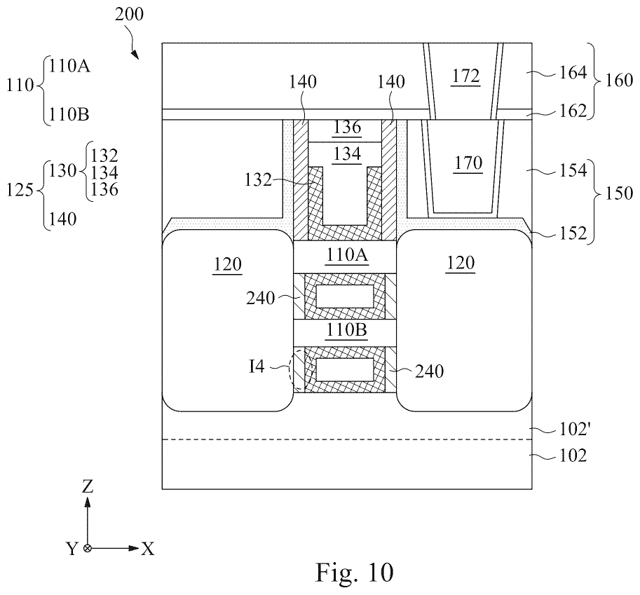

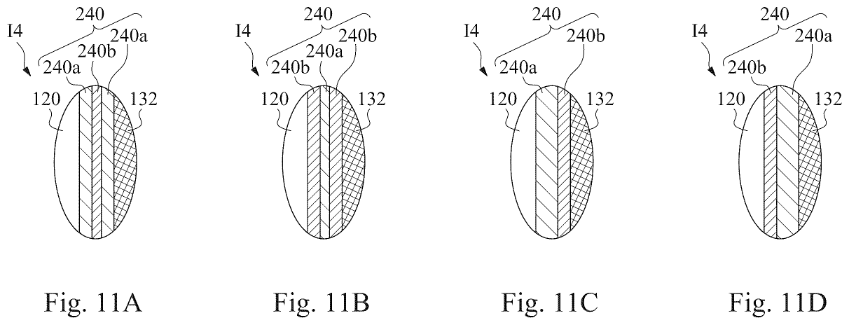

FIG. 10 is a cross-sectional view of a transistor 200, in portion or entirety, that may incorporate a laminated dielectric film, such as laminated dielectric film 10 described with reference to FIGS. 1-5 and/or other laminated dielectric films described herein, according to various aspects of the present disclosure. Transistor 200 is similar in many respects to transistor 100. Accordingly, similar features of transistor 200 and transistor 100 are identified by the same reference numbers for clarity and simplicity, such as substrate 102, fin structure 102′, channel 110, source/drains 120, gate structure 125, gate stack 130 (including gate dielectric 132, gate electrode 134, and hard mask 136), gate spacers 140, dielectric layer 150 (including CESL 152 and ILD layer 154), MLI structure connected to transistor 200, etc. FIGS. 11A-11D are enlarged views, in portion or entirety, of different configurations of a portion I4 of transistor 200 that may incorporate a laminated dielectric film, according to various aspects of the present disclosure. FIG. 10 and FIGS. 11A-11D are discussed concurrently herein for ease of description and understanding. FIG. 10 and FIGS. 11A-11D have been simplified for the sake of clarity to better understand the inventive concepts of the present disclosure. Additional features may be added in transistor 200, and some of the features described below may be replaced, modified, or eliminated in other embodiments of transistor 200.

In FIG. 10, transistor 200 is a gate-all-around (GAA) transistor. For example, channel 110 includes a channel layer 110A and a channel layer 110B, each of which is suspended and/or disposed over substrate 102. Channel layer 110A and channel layer 110B extend between source/drains 120, and channel layer 110A and channel layer 110B may be include a semiconductor material (and thus be referred to as semiconductor layers), such as those described herein. Channel layer 110A and channel layer 110B may be disposed over a protrusion of fin structure 102′ and/or substrate 102. Channel layer 110A and channel layer 110B may have cylindrical-shaped profiles (e.g., nanowires), rectangular-shaped profiles (e.g., nanobars), sheet-shaped profiles (e.g., nanosheets), or any other suitable shaped profile. In some embodiments, channel layer 110A and channel layer 110B have nanometer-sized dimensions and may be referred to as “nanostructures.” In some embodiments, channel layer 110A and channel layer 110B have sub-nanometer dimensions and/or other suitable dimensions.

Further, in transistor 200, gate stack 130 includes a top portion disposed over channel layer 110A, a middle portion disposed between channel layer 110A and channel layer 110B, and a bottom portion disposed between channel layer 110B and substrate 102 (e.g., a protrusion thereof). The top portion of gate stack 130 is disposed between gate spacers 140, the middle portion of gate stack 130 is disposed between respective inner spacers 240, and the bottom portion of gate stack 130 is disposed between respective inner spacers 240. In some embodiments, gate stack 130 may be disposed on a top, a bottom, and sidewalls of channel layer 110A and channel layer 110B in the cross-sectional view along the widthwise direction of the active region (e.g., along a lengthwise direction of gate stack 130). In such embodiments, gate stack 130 may surround and engage channel layer 110A and channel layer 110B. In some embodiments, gate stack 130 may wrap and/or partially surround channel layer 110A and channel layer 110B (i.e., be disposed on at least two sides thereof).

In the depicted embodiment, transistor 200 further includes inner spacers 240. In some embodiments, inner spacers 240 have boron-and-nitrogen containing laminate structures. The boron-and-nitrogen containing laminate structures include at least one crystalline boron nitride layer 240a, such as a hexagonal boron nitride layer, and at least one amorphous boron nitride layer 240b (see FIGS. 11A-11D). Crystalline boron nitride layer 240a is similar to crystalline boron nitride layers described herein, such as crystalline boron nitride layers 15, and amorphous boron nitride layer 240b is similar to amorphous boron nitride layers described herein, such as amorphous boron nitride layers 20. In some embodiments, inner spacers 240 having the boron-and-nitrogen containing laminate structures have a dielectric constant of about 1.8 to about 8.6 (1.8≤k≤8.6), such as a dielectric constant of about 3 (k≈3).

The boron-and-nitrogen containing laminate structure of inner spacers 240 may have various configurations, such as those depicted in FIGS. 11A-11D. For example, referring to FIG. 11A, the boron-and-nitrogen containing laminate structure of inner spacers 240 may include an amorphous boron nitride layer 240b disposed between crystalline boron nitride layers 240a. In such example, crystalline boron nitride layers 240a abut gate stack 130 (e.g., gate dielectric 132 and/or gate electrode 134 thereof) and source/drains 120. In another example, referring to FIG. 11B, the boron-and-nitrogen containing laminate structure of inner spacers 240 may include a crystalline boron nitride layer 240a disposed between amorphous boron nitride layers 240b. In such example, amorphous boron nitride layers 240b abut gate stack 130 and source/drains 120. In yet another example, referring to FIG. 11C and FIG. 11D, the boron-and-nitrogen containing laminate structure of inner spacers 240 may include a single crystalline boron nitride layer 240a and a single amorphous boron nitride layer 240b. In some embodiments of this example, amorphous boron nitride layer 240b may abut gate stack 130, while crystalline boron nitride layer 240a abuts source/drains 120, such as depicted in FIG. 11C. In other embodiments of this example, crystalline boron nitride layer 240a may abut gate stack 130, while amorphous boron nitride layer 240b abuts source/drains 120, such as depicted in FIG. 11D. In yet another example, the boron-and-nitrogen containing laminate structure of inner spacers 240 may include multiple crystalline boron nitride layers 240a interleaved with amorphous boron nitride layers 240b. For example, the boron-and-nitrogen containing laminate structure of inner spacers 240 may be configured as laminated dielectric film 10 described herein.

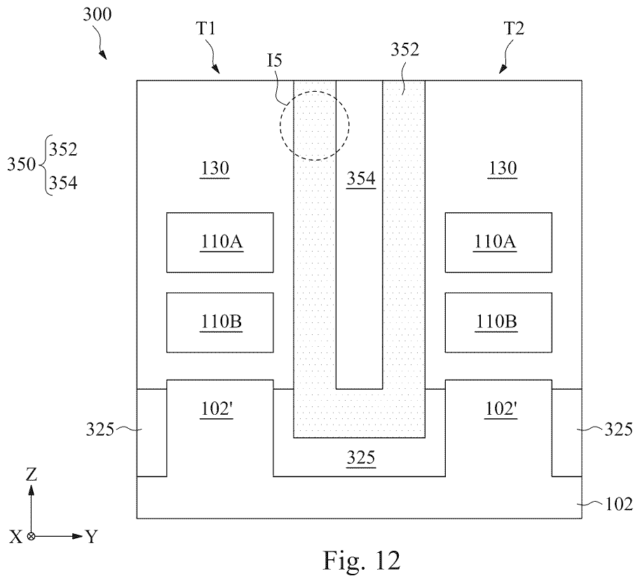

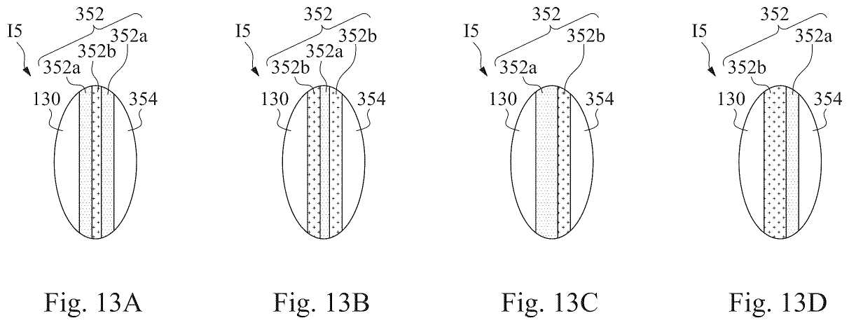

FIG. 12 is a cross-sectional view of a device 300, in portion or entirety, that may incorporate a laminated dielectric film, such as laminated dielectric film 10 described with reference to FIGS. 1-5 and/or other laminated dielectric films described herein, according to various aspects of the present disclosure. Device 300 is similar in many respects to transistor 100 and/or transistor 200. Accordingly, similar features of device 300, transistor 200, and transistor 100 are identified by the same reference numbers for clarity and simplicity. For example, device 300 includes a transistor T1 and a transistor T2, each of which includes a respective portion of substrate 102, a respective fin structure 102′, a respective channel 110 (including a respective channel layer 110A and a respective channel layer 110B), source/drains 120 (viewable along the x-direction), gate structure 125, gate stack 130 (including gate dielectric 132, gate electrode 134, and hard mask 136), gate spacers 140 (viewable along the x-direction), dielectric layer 150 (including CESL 152 and ILD layer 154) (viewable along the x-direction), etc. FIGS. 13A-13D are enlarged views, in portion or entirety, of different configurations of a portion I5 of device 300 that may incorporate a laminated dielectric film, according to various aspects of the present disclosure. FIG. 12 and FIGS. 13A-13D are discussed concurrently herein for ease of description and understanding. FIG. 12 and FIGS. 13A-13D have been simplified for the sake of clarity to better understand the inventive concepts of the present disclosure. Additional features may be added in device 300, and some of the features described below may be replaced, modified, or eliminated in other embodiments of device 300.

Device 300 further includes substrate isolation structures 325 that may electrically isolate active regions from adjacent active regions. For example, substrate isolation structures 325 may separate and electrically isolate the active region of transistor T1 from the active region of transistor T2 (e.g., fin structures 102′ thereof). Substrate isolation structures 325 include silicon oxide, silicon nitride, silicon oxynitride, other suitable isolation material (including, for example, silicon, oxygen, nitrogen, carbon, other suitable isolation constituent, etc.), or combinations thereof. Substrate isolation structures 325 may have a multilayer structure. For example, substrate isolation structures 325 may include a bulk dielectric (e.g., an oxide layer) over a dielectric liner (including, for example, silicon nitride, silicon oxide, silicon oxynitride, silicon oxycarbonitride, or combinations thereof). In another example, substrate isolation structures 325 may include a dielectric layer over a doped liner, such as a boron silicate glass (BSG) liner and/or a phosphosilicate glass (PSG) liner. Dimensions and/or characteristics of substrate isolation structures 325 are configured to provide a shallow trench isolation (STI) structure, a deep trench isolation (DTI) structure, a local oxidation of silicon (LOCOS) structure, other suitable isolation structure, or combinations thereof. In the depicted embodiment, substrate isolation structures 325 may be STIs, which are disposed on substrate 102.

Device 300 further includes a gate isolation structure 350, which includes a gate isolation liner 352 and a gate isolation bulk layer 354. Gate bulk isolation layer 354 includes any suitable dielectric material, such as those described herein (e.g., a low-k dielectric material). In some embodiments, gate isolation liner 352 has a boron-and-nitrogen containing laminate structure. The boron-and-nitrogen containing laminate structure includes at least one crystalline boron nitride layer 352a, such as a hexagonal boron nitride layer, and at least one amorphous boron nitride layer 352b (see FIGS. 13A-13D). Crystalline boron nitride layer 352a is similar to crystalline boron nitride layers described herein, such as crystalline boron nitride layers 15, and amorphous boron nitride layer 352b is similar to amorphous boron nitride layers described herein, such as amorphous boron nitride layers 20. In some embodiments, gate isolation liner 352 having the boron-and-nitrogen containing laminate structures has a dielectric constant of about 1.8 to about 8.6 (1.8≤k≤8.6), such as a dielectric constant of about 3 (k≈3).

The boron-and-nitrogen containing laminate structure of gate isolation liner 352 may have various configurations, such as those depicted in FIGS. 13A-13D. For example, referring to FIG. 13A, the boron-and-nitrogen containing laminate structure of gate isolation liner 352 may include an amorphous boron nitride layer 352b disposed between crystalline boron nitride layers 352a. In such example, crystalline boron nitride layers 352a abut gate stacks 130 (e.g., gate dielectric 132 and/or gate electrode 134 thereof), gate isolation bulk layer 354, and substrate isolation structure 325. In another example, referring to FIG. 13B, the boron-and-nitrogen containing laminate structure of gate isolation liner 352 may include a crystalline boron nitride layer 352a disposed between amorphous boron nitride layers 352b. In such example, amorphous boron nitride layers 352b abut gate stacks 130, gate isolation bulk layer 354, and substrate isolation structure 325. In yet another example, referring to FIG. 13C and FIG. 13D, the boron-and-nitrogen containing laminate structure of gate isolation liner 352 may include a single crystalline boron nitride layer 352a and a single amorphous boron nitride layer 352b. In some embodiments of this example, amorphous boron nitride layer 352b may abut gate stacks 130 and substrate isolation structure 325, while crystalline boron nitride layer 352a abuts gate isolation bulk layer 354, such as depicted in FIG. 13C. In other embodiments of this example, crystalline boron nitride layer 352a may abut gate stacks 130 and substrate isolation structure 325, while amorphous boron nitride layer 352b abuts gate isolation bulk layer 354, such as depicted in FIG. 13D. In yet another example, the boron-and-nitrogen containing laminate structure of gate isolation liner 352 may include multiple crystalline boron nitride layers 352a interleaved with amorphous boron nitride layers 352b. For example, the boron-and-nitrogen containing laminate structure may be configured as laminated dielectric film 10 described herein.

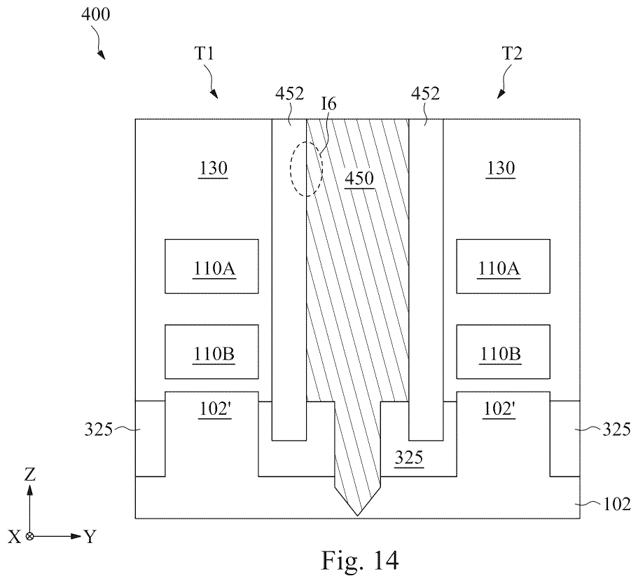

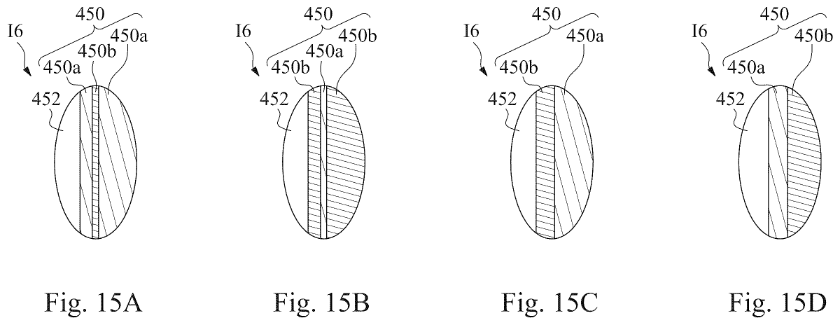

FIG. 14 is a cross-sectional view of a device 400, in portion or entirety, that may incorporate a laminated dielectric film, such as laminated dielectric film 10 described with reference to FIGS. 1-5 and/or other laminated dielectric films described herein, according to various aspects of the present disclosure. Device 400 is similar in many respects to device 300. Accordingly, similar features of device 400 and device 300 are identified by the same reference numbers for clarity and simplicity. For example, device 400 includes transistor T1 and transistor T2, each of which includes a respective portion of substrate 102, a respective fin structure 102′, a respective channel 110 (including a respective channel layer 110A and a respective channel layer 110B), source/drains 120 (viewable along the x-direction), gate structure 125, gate stack 130 (including gate dielectric 132, gate electrode 136, and hard mask 136), gate spacers 140 (viewable along the x-direction), dielectric layer 150 (including CESL 152 and ILD layer 154) (viewable along the x-direction), substrate isolation structures 325, etc. FIGS. 15A-15D are enlarged views, in portion or entirety, of different configurations of a portion I6 of device 400 that may incorporate a laminated dielectric film, according to various aspects of the present disclosure. FIG. 14 and FIGS. 15A-15D are discussed concurrently herein for ease of description and understanding. FIG. 14 and FIGS. 15A-15D have been simplified for the sake of clarity to better understand the inventive concepts of the present disclosure. Additional features may be added in device 400, and some of the features described below may be replaced, modified, or eliminated in other embodiments of device 400.

Device 400 further includes a gate isolation structure 450. Gate isolation structure 450 is disposed over substate isolation structure 325. In some embodiments, gate isolation structure 450 extends into substrate isolation structure 325, such as depicted. In some embodiments, gate isolation structure 450 extends into substrate 102, such as depicted. In some embodiments, dielectric layers 452 may be disposed between gate isolation structure 450 and gate stacks 130 (e.g., sidewalls thereof). In some embodiments, dielectric layers 452 extend into substrate isolation structures 325, such as depicted. Dielectric layers 452 include any suitable dielectric material, such as those described herein (e.g., a low-k dielectric material).

In some embodiments, gate isolation structure 450 has a boron-and-nitrogen containing laminate structure. The boron-and-nitrogen containing laminate structure includes at least one crystalline boron nitride layer 450a, such as a hexagonal boron nitride layer, and at least one amorphous boron nitride layer 450b (see FIGS. 15A-15D). Crystalline boron nitride layer 450a is similar to crystalline boron nitride layers described herein, such as crystalline boron nitride layers 15, and amorphous boron nitride layer 450b is similar to amorphous boron nitride layers described herein, such as amorphous boron nitride layers 20. In some embodiments, gate isolation structure 450 having the boron-and-nitrogen containing laminate structures has a dielectric constant of about 1.8 to about 8.6 (1.8≤k≤8.6), such as about 3 (k≈3).

The boron-and-nitrogen containing laminate structure of gate isolation structure 450 may have various configurations, such as those depicted in FIGS. 15A-15D. For example, referring to FIG. 15A, the boron-and-nitrogen containing laminate structure of gate isolation structure 450 may include an amorphous boron nitride layer 450b disposed between crystalline boron nitride layers 450a. In such example, crystalline boron nitride layers 450a may abut dielectric layers 452 and substrate isolation structure 325. In some embodiments, dielectric layers 452 are omitted, and crystalline boron nitride layers 450a may abut gate stacks 130 (e.g., gate dielectric 132 and/or gate electrode 134 thereof). In another example, referring to FIG. 15B, the boron-and-nitrogen containing laminate structure of gate isolation structure 450 may include a crystalline boron nitride layer 450a disposed between amorphous boron nitride layers 450b. In such example, amorphous boron nitride layers 450b abut dielectric layers 452 and substrate isolation structure 325. In some embodiments, dielectric layers 452 are omitted, and amorphous boron nitride layers 450b may abut gate stacks 130. In yet another example, referring to FIG. 15C and FIG. 15D, the boron-and-nitrogen containing laminate structure of gate isolation structure 450 may include a single crystalline boron nitride layer 450a and a single amorphous boron nitride layer 450b. In some embodiments of this example, amorphous boron nitride layer 450b may abut dielectric layers 452 (or gate stacks 130 where dielectric layers 452 are omitted) and substrate isolation structure 325, such as depicted in FIG. 15C. In other embodiments of this example, crystalline boron nitride layer 450a may abut dielectric layers 452 (or gate stacks 130 where dielectric layers 452 are omitted) and substrate isolation structure 325, such as depicted in FIG. 15D. In yet another example, the boron-and-nitrogen containing laminate structure of gate isolation structure 450 may include multiple crystalline boron nitride layers 450a interleaved with amorphous boron nitride layers 450b. For example, the boron-and-nitrogen containing laminate structure may be configured as laminated dielectric film 10 described herein.

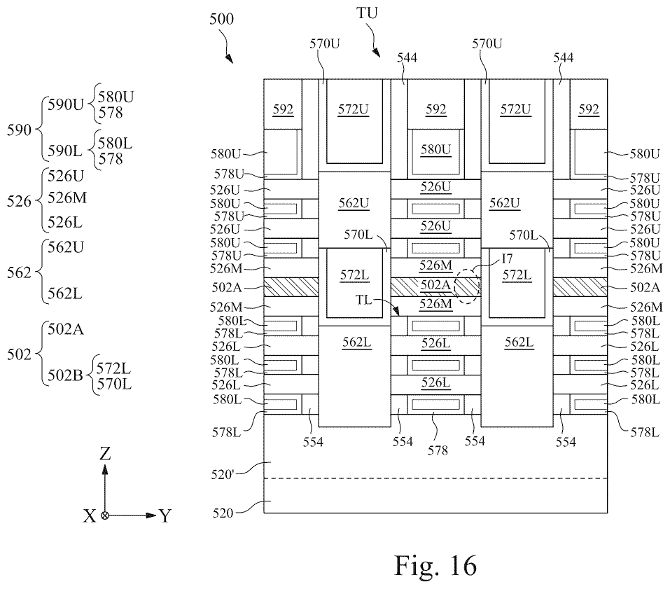

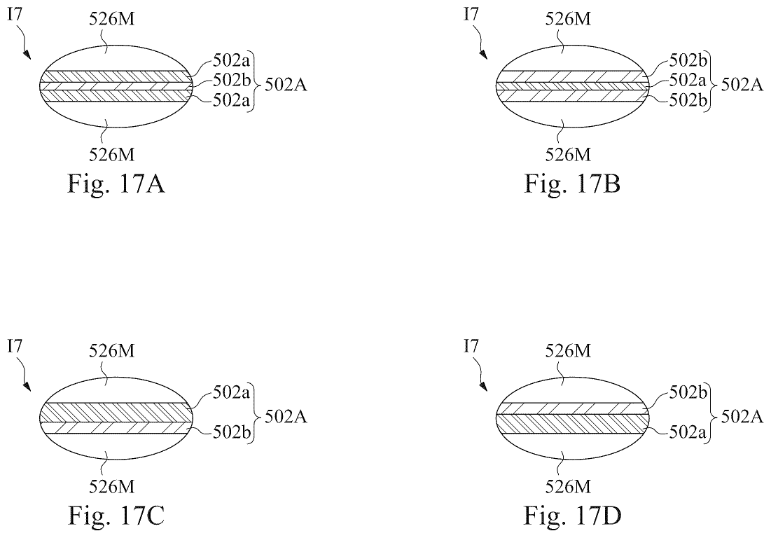

FIG. 16 is a cross-sectional view of a device 500, in portion or entirety, that may incorporate a laminated dielectric film, such as laminated dielectric film 10 described with reference to FIGS. 1-5 and/or other laminated dielectric films described herein, according to various aspects of the present disclosure. FIGS. 17A-17D are enlarged views, in portion or entirety, of different configurations of a portion I7 of device 500 that may incorporate a laminated dielectric film, according to various aspects of the present disclosure. FIG. 16 and FIGS. 17A-17D are discussed concurrently herein for ease of description and understanding. FIG. 16 and FIGS. 17A-17D have been simplified for the sake of clarity to better understand the inventive concepts of the present disclosure. Additional features may be added in stacked device structure 500, and some of the features described below may be replaced, modified, or eliminated in other embodiments of stacked device structure 500.

Device 500 may include a device stack, such as a transistor stack, having an upper device, such as an upper transistor TU, vertically stacked over a lower device, such as a lower transistor TL. Upper transistor TU and lower transistor TL may be separated and/or electrically isolated from one another by isolation structure 502, which is described further below. In some embodiments, lower transistor TL and upper transistor TU are transistors of opposite conductivity type. For example, lower transistor TL is a p-type transistor, and upper transistor TU is an n-type transistor, or vice versa. In such embodiments, lower transistor TL and upper transistor TU may form a CFET. In some embodiments, lower transistor TL and upper transistor TU are transistors of a same conductivity type. For example, lower transistor TL and upper transistor TU may both be n-type transistors or both p-type transistors.

Upper transistor TU includes various features and/or components, such as semiconductor layers 526U, semiconductor layers 526M, gate spacers 544, inner spacers 554, source/drains 562U, a contact etch stop layer (CESL) 570U, an interlayer dielectric (ILD) layer 572U, gate dielectrics 578U and gate electrodes 580U (which collectively form gate stacks 590U), and hard masks 592. Lower transistor TL also includes various features and/or components, such as a protrusion 520′ (which may be an extension of substrate 520), semiconductor layers 526L, semiconductor layers 526M, substrate isolation structures, inner spacers 554, source/drains 562L, a CESL 570L, an ILD layer 572L, and gate dielectrics 578L and gate electrodes 580L (which collectively form gate stacks 590L). Source/drains 562U and source/drains 562L may collectively be referred to as source/drains 562. A respective gate stack 590U and a respective gate stack 590L may collectively be referred to as a gate 590 of the transistor stack. As noted, isolation structure 502 may be between upper transistor TU and lower transistor TL. In the depicted embodiment, isolation structure 502 includes an isolation structure 502A, which may be disposed between and separate gate stack 590U from gate stack 590L, and an isolation structure 502B (formed by CESL 570L and ILD layer 572L), which may be disposed between and separate source/drains 562U from source/drains 562L. Isolation structures 502A may thus function as channel isolation structures and/or gate isolation structures, and isolation structures 502B may thus function as source/drain isolation structures.

In some embodiments, isolation structures 502A have a boron-and-nitrogen containing laminate structure. The boron-and-nitrogen containing laminate structure includes at least one crystalline boron nitride layer 502a, such as a hexagonal boron nitride layer, and at least one amorphous boron nitride layer 502b (see FIGS. 17A-17D). Crystalline boron nitride layer 502a is similar to crystalline boron nitride layers described herein, such as crystalline boron nitride layers 15, and amorphous boron nitride layer 502b is similar to amorphous boron nitride layers described herein, such as amorphous boron nitride layers 20. In some embodiments, isolation structures 502A having the boron-and-nitrogen containing laminate structure have a dielectric constant of about 1.8 to about 8.6 (1.8≤k≤8.6), such as about 3 (k≈3).

The boron-and-nitrogen containing laminate structure of isolation structures 502A may have various configurations, such as those depicted in FIGS. 17A-17D. For example, referring to FIG. 17A, the boron-and-nitrogen containing laminate structure of isolation structures 502A may include an amorphous boron nitride layer 502b disposed between crystalline boron nitride layers 502a. In such example, crystalline boron nitride layers 502a may abut semiconductor layers 526M and CESL 570L. In another example, referring to FIG. 17B, the boron-and-nitrogen containing laminate structure of isolation structures 502A may include a crystalline boron nitride layer 502a disposed between amorphous boron nitride layers 502b. In such example, amorphous boron nitride layers 502b abut semiconductor layers 526M and CESL 570L. In yet other examples, referring to FIG. 17C and FIG. 17D, the boron-and-nitrogen containing laminate structure of isolation structures 502A may include a single crystalline boron nitride layer 502a and a single amorphous boron nitride layer 502b. For example, amorphous boron nitride layer 502b and crystalline boron nitride layer 502a may abut semiconductor layers 526M and CESL 570L. In yet another example, the boron-and-nitrogen containing laminate structure of isolation structures 502A may include multiple crystalline boron nitride layers 502a interleaved with amorphous boron nitride layers 502b. For example, the boron-and-nitrogen containing laminate structure may be configured as laminated dielectric film 10.

In the depicted embodiment, lower transistor TL is a GAA transistor. For example, lower transistor TL has two channels provided by semiconductor layers 526L (also referred to as channel layers or channels), which are suspended over substrate 520 and extend between respective source/drains (e.g., source/drains 562L). In some embodiments, lower transistor TL includes more or less channels (and thus more or less semiconductor layers 526L). Lower transistor TL further has gate stack 590L disposed over and engaging its semiconductor layers 526L. Gate stack 590L is disposed between source/drains 562L, and inner spacers 554 are disposed between gate stack 590L and source/drains 562L. Along a gate widthwise direction (e.g., in a y-Z plane), gate stack 590L is disposed over top semiconductor layer 526L, between semiconductor layers 526L, and between bottom semiconductor layer 526L and substrate 520. Along a gate lengthwise direction (e.g., in a X-Z plane), gate stack 590L wraps around semiconductor layers 526L. During operation of the GAA transistor, current can flow through semiconductor layers 526L and between source/drains 562L. Semiconductor layers 526M (also referred to as dummy channel layers or dummy channels) are suspended over substrate 520 and extend between respective isolation structures 502B, and isolation structures 502A are disposed between semiconductor layers 526M of lower transistor TL and upper transistor TU.

In the depicted embodiment, upper transistor TU is also a GAA transistor. For example, upper transistor TU has two channels provided by semiconductor layers 526U (also referred to as channel layers or channels), which are suspended over substrate 520 and extend between respective source/drains (e.g., source/drains 562U). In some embodiments, upper transistor TU includes more or less channels/semiconductor layers 526U. Upper transistor TU further has gate stack 590U disposed over and engaging its semiconductor layers 526U. Gate stack 590U is disposed between source/drains 562U, gate stack 590U is disposed between respective gate spacers 544, inner spacers 554 are disposed between gate stack 590U and source/drains 562U, and hard mask 592 is disposed over gate stack 590U. Along a gate widthwise direction, gate stack 590U is over top semiconductor layer 526U, between semiconductor layers 526U, and between bottom semiconductor layer 526U and semiconductor layer 526M. Along a gate lengthwise direction, gate stack 590U wraps around semiconductor layers 526U. During operation of the GAA transistor, current can flow through semiconductor layers 526U and between source/drains 562U.

Substrate 520 may be configured similar to substrate 102 described herein, and protrusion 520′ may be configured similar to protrusion and/or fin structure 102′ described herein. Semiconductor layers 526U, semiconductor layers 526M, and semiconductor layers 526L (collectively referred to as semiconductor layers 526) include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In the depicted embodiment, substrate 520 semiconductor layers 526U, semiconductor layers 526M, and semiconductor layers 526L include silicon. In some embodiments, semiconductor layers 526U and semiconductor layers 526L include different semiconductor materials, such as silicon and silicon germanium, respectively, or vice versa.

Gate spacers 544 are disposed along sidewalls of upper portions of gate stacks 590U, inner spacers 554 are disposed under gate spacers 544 along sidewalls of gate stacks 590U and/or gate stacks 590L, and fin/protrusion spacers may be disposed along sidewalls of protrusions 520′. Inner spacers 554 are between semiconductor layers 526 and between bottom semiconductor layers 526 and protrusions 520′. Gate spacers 544, inner spacers 554, and fin spacers include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Gate spacers 544, inner spacers 554, and fin spacers may include different materials and/or different configurations (e.g., different numbers of layers). In some embodiments, gate spacers 544, inner spacers 554, fin spacers, or combinations thereof have a multilayer structure. In some embodiments, gate spacers 544 and/or fin spacers include more than one set of spacers, such as seal spacers, offset spacers, sacrificial spacers, dummy spacers, main spacers, or combinations thereof. The various sets of spacers may have different compositions. In some embodiments, gate spacers 544 are similar to gate spacers 140 described herein (e.g., gate spacers 544 may have boron-and-nitrogen containing laminate structures). In some embodiments, inner spacers 554 are similar to inner spacers 240 described herein (e.g., inner spacers 240 may have boron-and-nitrogen containing laminate structures).

Gate 590 is disposed between source/drain stacks. Each source/drain stack includes a respective source/drain 562U, a respective source/drain 562L, and a respective isolation structure 502A disposed therebetween. Source/drains 562L and source/drains 562U include semiconductor material, and source/drains 562L and source/drains 562U may be doped with n-type dopants and/or p-type dopants. In some embodiments, source/drains 562L and source/drains 562U are formed of epitaxially grown/deposited semiconductor material(s), and source/drains 562L and source/drains 562U may be referred to as epitaxial source/drains. Source/drains 562L and source/drains 562U may have the same or different compositions and/or materials depending on configurations of their respective transistors. In some embodiments (e.g., when forming portions of n-type transistors), source/drains 562L and/or source/drains 562U include silicon doped with carbon, phosphorous, arsenic, other n-type dopant, or combinations thereof (e.g., Si:C epitaxial source/drains, Si:P epitaxial source/drains, or Si:C:P epitaxial source/drains). In some embodiments (e.g., when forming portions of p-type transistors), source/drains 562L and/or source/drains 562U include silicon germanium or germanium doped with boron, other p-type dopant, or combinations thereof (e.g., Si:Ge:B epitaxial source/drains). In some embodiments, source/drains 562L include silicon germanium doped with boron, and source/drains 562U include silicon doped with phosphorous, or vice versa. In some embodiments, doped regions, such as heavily doped source/drain (HDD) regions, lightly doped source/drain (LDD) regions, other doped regions, or combinations thereof, are disposed in source/drains 562L and/or source/drains 562U. In some embodiments, source/drains 562L and/or source/drains 562U include multiple semiconductor layer, and the semiconductor layers may include the same or different materials, compositions, dopant type, dopant concentrations, thicknesses, etc. In some embodiments, source/drains 562L and/or source/drains 562U include materials and/or dopants that achieve desired tensile stress and/or compressive stress in adjacent channel regions (e.g., formed by semiconductor layers 526U and semiconductor layers 526L). As used herein, source/drain region, source/drain, epitaxial source/drain, epitaxial source/drain feature, etc. may refer to a source of a device (e.g., upper transistor TU and/or lower transistor TL), a drain of a device (e.g., upper transistor TU and/or lower transistor TL), or a source and/or a drain of multiple devices.

ILD layer 572U and ILD layer 572L include a dielectric material, such as those described herein. CESL 570L and CESL 570U include a material different than a material of ILD layer 572L and ILD layer 572U, respectively. ILD layer 572U and/or ILD layer 572L may be configured similar to the ILD layers described herein (e.g., ILD layer 154). CESL 570U and/or CESL 570L may be configured similar to the CESLs described herein (e.g., CESL 152). In some embodiments, CESL 570U and/or CESL 570L have boron-and-nitrogen containing laminate structures, such as described with reference to CESL 152.

Gate dielectrics 578U and gate dielectrics 578L each include at least one dielectric gate layer. Gate dielectrics 578U and gate dielectrics 578L may collectively be referred to as gate dielectrics 578. Gate electrodes 580U and gate electrodes 580L are disposed over gate dielectrics 578U and gate dielectrics 578L, respectively. Gate dielectrics 578U and gate dielectrics 578L may have the same or different compositions, materials, layers, configurations, or combinations thereof. Gate electrodes 580U and gate electrodes 580L may have the same or different compositions, materials, layers, configurations, or combinations thereof. Gate electrodes 580U and gate electrodes 580L each include at least one electrically conductive gate layer formed of an electrically conductive material. Gate dielectrics 578U and/or gate dielectrics 578L may be similar to gate dielectric 132 described herein. Gate electrodes 580U and/or gate electrodes 580L may be similar to gate electrode 134 described herein.

Hard masks 592 include a material that is different than ILD layer 572U and/or subsequently formed ILD layers to achieve etch selectivity during subsequent etching processes. In some embodiments, hard masks 592 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard masks 592 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof. In some embodiments, a dielectric constant of hard masks 592 is greater than a dielectric constant of isolation structures 502A, a dielectric constant of ILD layer 572U, a dielectric constant of CESL 570L, a dielectric constant of gate spacers 544, or combination thereof.

The present disclosure provides for many different embodiments. An exemplary device includes a dielectric layer having a laminate structure. The laminate structure includes a crystalline boron nitride layer and an amorphous boron nitride layer. In some embodiments, the crystalline boron nitride layer is a hexagonal boron nitride layer. In some embodiments, a thickness of the crystalline boron nitride layer is greater than a thickness of the amorphous boron nitride layer. In some embodiments, the crystalline boron nitride layer is a first crystalline boron nitride layer, the laminate structure further includes a second crystalline boron nitride layer, and the amorphous boron nitride layer is disposed between the first crystalline boron nitride layer and the second crystalline boron nitride layer. In some embodiments, the first crystalline boron nitride layer and the second crystalline boron nitride layer are hexagonal boron nitride layers.

In some embodiments, the dielectric layer is a gate spacer. In some embodiments, the dielectric layer is an inner spacer. In some embodiments, the dielectric layer is a contact etch stop layer. In some embodiments, the dielectric layer is a gate isolation layer.

An exemplary transistor includes a channel, a first source/drain, and a second source/drain. The channel is between the first source/drain and the second source/drain. The transistor further includes a gate stack disposed over the channel and laminated boron nitride gate spacers disposed along sidewalls of the gate stack. In some embodiments, each of the laminated boron nitride gate spacers includes a crystalline boron nitride layer and an amorphous boron nitride layer. In some embodiments, the amorphous boron nitride layer is between a respective one of the sidewalls of the gate stack and the crystalline boron nitride layer. In some embodiments, the crystalline boron nitride layer is between a respective one of the sidewalls of the gate stack and the amorphous boron nitride layer. In some embodiments, each of the laminated boron nitride gate spacers includes an amorphous boron nitride layer between a first crystalline boron nitride layer and a second crystalline boron nitride layer. In some embodiments, each of the laminated boron nitride gate spacers includes a crystalline boron nitride layer between a first amorphous boron nitride layer and a second amorphous boron nitride layer. In some embodiments, each of the laminated boron nitride gate spacers includes at least two crystalline boron nitride layers and at least one amorphous boron nitride layer.

An exemplary method includes forming a dielectric layer having a laminate structure. The laminate structure includes a crystalline boron nitride layer and an amorphous boron nitride layer. In some embodiments, the dielectric layer is a gate spacer, and the forming the dielectric layer includes forming the gate spacer along a sidewall of a gate stack. In some embodiments, the amorphous boron nitride layer is disposed between the sidewall of the gate stack and the crystalline boron nitride layer. In some embodiments, the crystalline boron nitride layer is disposed between the sidewall of the gate stack and the amorphous boron nitride layer. In some embodiments, forming the dielectric layer includes performing a deposition process, and the deposition process implements a borazine precursor. In some embodiments, the deposition process further implements a nitrogen-containing plasma. In some embodiments, the deposition process implements a deposition temperature of about 200° C. to about 400° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
a device that includes:
an active region, wherein the active region includes a channel region disposed between source/drain regions,
a gate stack disposed over the channel region, and
an interconnect structure disposed over the gate stack; and
wherein a portion of the device is formed by a dielectric layer having a laminate structure, wherein the laminate structure includes:
a crystalline boron nitride layer, and
an amorphous boron nitride layer.

2. The device structure of claim 1, wherein the crystalline boron nitride layer is a hexagonal boron nitride layer.

3. The device structure of claim 1, wherein:
the crystalline boron nitride layer is a first crystalline boron nitride layer; and
the laminate structure further includes a second crystalline boron nitride layer, wherein the amorphous boron nitride layer is disposed between the first crystalline boron nitride layer and the second crystalline boron nitride layer.

4. The device structure of claim 3, wherein the first crystalline boron nitride layer and the second crystalline boron nitride layer are hexagonal boron nitride layers.

5. The device structure of claim 1, wherein a thickness of the crystalline boron nitride layer is greater than a thickness of the amorphous boron nitride layer.

6. The device structure of claim 1, wherein the device further includes gate spacers disposed along sidewalls of the gate stack and the gate spacers are the portion of the device formed by the dielectric layer.

7. The device structure of claim 1, wherein the device further includes inner spacers disposed between the gate stack and the source/drain regions and the inner spacers are the portion of the device formed by the dielectric layer.

8. The device structure of claim 1, wherein the device further includes a contact etch stop layer disposed over the source/drain regions and the contact etch stop layer is the portion of the device formed by the dielectric layer.

9. The device structure of claim 1, wherein the device further includes a gate isolation layer disposed adjacent to the gate stack and the gate isolation layer is the portion of the device formed by the dielectric layer.

10. A transistor comprising:
a channel;
a first source/drain and a second source/drain, wherein the channel is between the first source/drain and the second source/drain;
a gate stack disposed over the channel, wherein the gate stack includes a gate dielectric and a gate electrode, wherein the gate electrode is disposed over the gate dielectric; and
laminated boron nitride gate spacers disposed along sidewalls of the gate stack, wherein a dielectric constant of the gate dielectric is greater than a dielectric constant of the laminated boron nitride gate spacers.

11. The transistor of claim 10, wherein each of the laminated boron nitride gate spacers includes a crystalline boron nitride layer and an amorphous boron nitride layer.

12. The transistor of claim 11, wherein the amorphous boron nitride layer is between a respective one of the sidewalls of the gate stack and the crystalline boron nitride layer.

13. The transistor of claim 11, wherein the crystalline boron nitride layer is between a respective one of the sidewalls of the gate stack and the amorphous boron nitride layer.

14. The transistor of claim 10, wherein each of the laminated boron nitride gate spacers includes an amorphous boron nitride layer between a first crystalline boron nitride layer and a second crystalline boron nitride layer.

15. The transistor of claim 10, wherein each of the laminated boron nitride gate spacers includes a crystalline boron nitride layer between a first amorphous boron nitride layer and a second amorphous boron nitride layer.

16. A method comprising:
forming a device that includes:
an active region, wherein the active region includes a channel region disposed between source/drain regions,
a gate stack disposed over the channel region, and
an interconnect structure disposed over the gate stack; and
wherein the forming the device includes forming a portion of the device by a dielectric layer having a laminate structure, wherein the laminate structure includes a crystalline boron nitride layer and an amorphous boron nitride layer.

17. The method of claim 16, wherein the device further includes gate spacers disposed along sidewalls of the gate stack, the gate spacers are the portion of the device formed by the dielectric layer, and the amorphous boron nitride layer is disposed between the sidewalls of the gate stack and the crystalline boron nitride layer.

18. The method of claim 16, wherein the device further includes gate spacers disposed along sidewalls of the gate stack, the gate spacers are the portion of the device formed by the dielectric layer, and the crystalline boron nitride layer is disposed between the sidewalls of the gate stack and the amorphous boron nitride layer.

19. The method of claim 16, wherein the forming the dielectric layer includes performing a deposition process, wherein the deposition process implements a borazine precursor and a nitrogen-containing plasma.

20. The method of claim 19, wherein the deposition process implements a deposition temperature of about 200° C. to about 400° C.
